(19) United States
(12) Patent Application Publication
(10) Pub. No.: US 2009/0261462 A1
(43) Pub. Date: Oct. 22, 2009

(54) SEMICONDUCTOR PACKAGE WITH STACKED DIE ASSEMBLY

(76) Inventor: Jocel Gomez, Cebu (PH)

Correspondence Address: KENNETH E. HORTON;KIRTON & MCCONKLE, 60 EAST SOUTH TEMPLE, SUITE 1800, SALTLAKE CITY, UT, 84111, US

(21) Appl. No.: 12/103,838

(22) Filed: Apr. 16, 2008

(51) Int. Cl. H01L 23/495; H01L 21/58

(52) U.S. Cl. 257/673; 438/109; 257/E23.031; 257/E21.505

(57) ABSTRACT

This application relates to semiconductor packages comprising stacked die assemblies. In some cases, the stacked dies comprise a first die containing gate driver IC that is stacked on a first surface of a second IC die. A second surface of the second IC die can be bumped for connection to one or more bump attach pads. The first die can be wire bonded to one or more bond attach pads. In some instances, the semiconductor packages include a leadframe clip that connects with the drain on the first die. In such instances, the gate driver IC of the first die can be stacked on a first surface of the leadframe clip and a second surface of the leadframe clip can be stacked on the first surface of the second IC die. The semiconductor packages can be molded and/or configured into a ball grid array (“BGA”) or a land grid array (“LGA”) configuration. Other embodiments are described.

### FIELD

This application relates generally to packaged semiconductor devices or semiconductor packages. More specifically, this application relates to molded ball grid array or land grid array semiconductor packages that include a stacked die assembly.

### BACKGROUND

Semiconductor packages are well known in the art. Often, these packages may include one or more semiconductor devices, such as an integrated circuit (“IC”) die or chip, which may be connected to a die pad that is centrally formed in a lead frame. In some cases, bond wires electrically connect the IC die to a series of terminals that serve as an electrical connection to an external device, such as a printed circuit board (“PCB”). An encapsulating material can be used to cover the bond wires, the IC die, the terminals, and/or other components of the semiconductor device to form the exterior of the semiconductor package. A portion of the terminals and possibly a portion of the die pad may be externally exposed from the encapsulating material. In this manner, the die may be protected from environmental hazards—such as moisture, contaminants, corrosion, and mechanical shock—while being electrically and mechanically connected to an intended device that is external to the semiconductor package.

After it has been formed, the semiconductor package is often used in an ever growing variety of electronic applications, such as disk drives, USB controllers, portable computer devices, cellular phones, and so forth. Depending on the die and the electronic application, the semiconductor package may be highly miniaturized and may need to be as small as possible.

However, many current semiconductor packages may have shortcomings that limit their use. For example, some semiconductor packages comprising an IC die may require the use of a gate driver IC to function. Thus, these semiconductor packages comprising a die may need to be used in conjunction with a separate package that contains a gate driver IC. In another example, some semiconductor packages that use wire bonding to connect the die to the terminals may have an undesirably high Rd, response. In still another example, some semiconductor packages may be used as moldless assemblies, and thereby be exposed to environmental hazards.

### SUMMARY

This application relates to semiconductor packages comprising stacked die assemblies. In some cases, the stacked dies comprise a first die containing gate driver IC that is stacked on a first surface of a second IC die. A second surface of the second IC die can be bumped for connection to one or more bump attach pads. The first die can be wire bonded to one or more bond attach pads. In some instances, the semiconductor packages include a leadframe clip that connects with the drain on the first die. In such instances, the gate driver IC of the first die can be stacked on a first surface of the leadframe clip and a second surface of the leadframe clip can be stacked on the first surface of the second IC die. The semiconductor packages can be molded and/or configured into a ball grid array (“BGA”) or a land grid array (“LGA”) configuration.

### BRIEF DESCRIPTION OF THE DRAWINGS

The following description can be better understood in light of the Figures, in which:

FIG. 1a and 1b contain cross-sectional views of some embodiments of a semiconductor package comprising a stacked die assembly;

FIGS. 2a and 2b each contain a different view of some embodiments of a semiconductor package;

FIG. 2c contains a depiction of some embodiments of solder bumping that includes a stud;

FIGS. 3a and 3b contain views of some embodiments of an IC die;

FIGS. 4a through 4c contain different views of some embodiments of an attach pad;

FIG. 5 illustrates some embodiments of a leadframe with an array of attach pads;

FIGS. 5a through 5f depict some embodiments of a process flow for making a lead frame substrate;

FIGS. 6a through 6h-2 illustrate some embodiments of an assembly process flow for producing some embodiments of a semiconductor package;

FIGS. 7a through 7e depict various views of some embodiments of a semiconductor package;

FIGS. 8a and 8b illustrate some embodiments of a semiconductor package comprising a leadframe clip;

FIGS. 9a and 9b illustrate some embodiments of an IC die;

FIG. 10a and 10b illustrate some embodiments of a semiconductor package comprising the leadframe clip;

FIGS. 11a through 11e depict various views of some embodiments of a semiconductor package that includes a leadframe clip; and

FIGS. 12 and 13 illustrate some embodiments of a semiconductor package and corresponding land patterns.

The Figures illustrate specific aspects of the semiconductor packages comprising the stacked die assembly and associated methods of making and using such packages. Together with the following description, the Figures demonstrate and explain the principles of the semiconductor packages comprising the stacked die assembly and associated methods. In the drawings, the thickness of layers and regions are exaggerated for clarity. It will also be understood that when a layer, component, or substrate is referred to as being “on” another layer, component, or substrate, it can be directly on the other layer, component, or substrate, or intervening layers may also be present. The same reference numerals in different drawings represent the same element, and thus their descriptions will not be repeated.

### DETAILED DESCRIPTION

The following description supplies specific details in order to provide a thorough understanding. Nevertheless, the skilled artisan would understand that the semiconductor packages described herein that comprise a stacked die assembly and methods for making and using such packages can be implemented and used without employing these specific details. For example, while the detailed description focuses on stacked die assemblies using a BGA or an LGA configuration, the described die assemblies can be used with any known interface connection, whether leaded or leadless. Furthermore, the stacked die assemblies can be used in conjunction with any other type of semiconductor package such as active devices (like diodes or transistors) or passive devices.

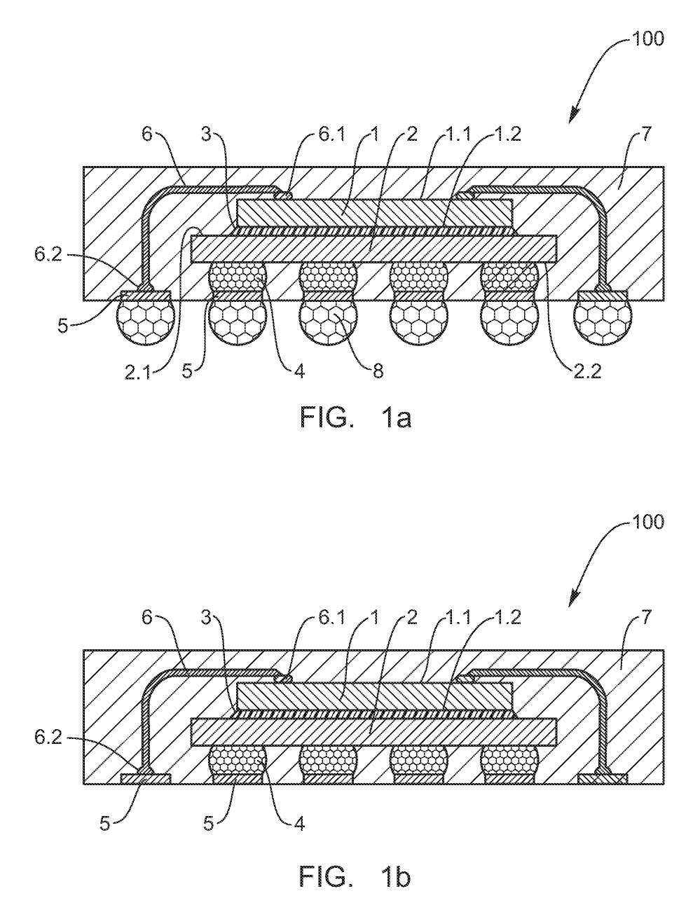

The Figures illustrate some embodiments of a stacked die assembly in a molded semiconductor package. Specifically, FIG. 1a shows some embodiments where the semiconductor package 100 comprises a stacked assembly that includes multiple dies (e.g., a gate driver IC 1 and an IC die 2), a die attach layer 3, solder bumps 4, bump/bond attach pads (“attach pad”) 5, bonded wires 6, bond stitch on balls (“BSOB”) 6.1, ball formed bonds 6.2, and/or a molding compound 7. While FIG. 1b illustrates some embodiments where the package 100 comprises a molded LGA package, FIG. 1a shows other embodiments where the package 100 comprises a molded BGA package that comprises external solder ball terminals 8. In addition, the semiconductor package may also contain any other known component, such as a leadframe clip.

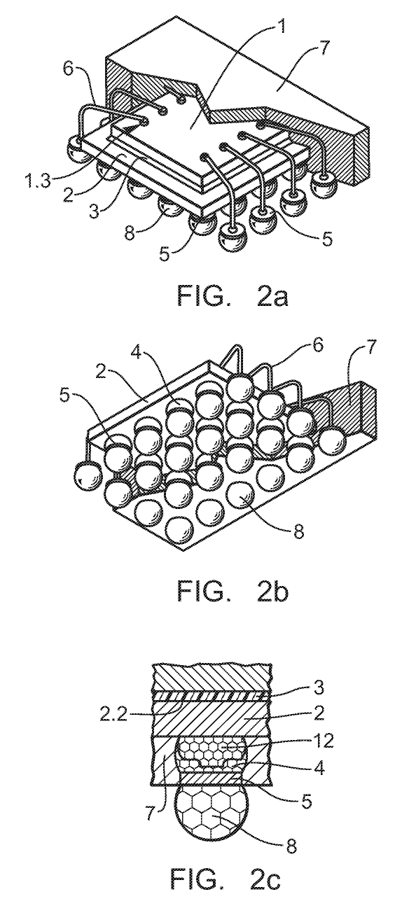

The package comprises multiple stacked dies. In some embodiments, the number of stacked dies is two. But in other embodiments, the number of dies can range from three or more. The semiconductor package can comprise any type of die that is suitable for use in a semiconductor package comprising a stacked assembly. By way of non-limiting example, FIG. 1 a shows the dies can comprise a first die 1 containing a gate driver IC (or gate driver die) and/or a second die 2 containing any known IC (or IC die).

Where the first die comprises a gate driver, the gate driver may be any known gate driver IC. By way of non-limiting example, the gate driver may be a high-side, a low side, a dual-gate, half-bridge, or other type of gate driver. As shown in FIG. 1b, the gate driver may have a first surface 1.1 and a second surface 1.2. The first surface may have one or more input and/or output connection terminals 1.3, as illustrated by FIG. 2a.

The first die 1 (and therefore the semiconductor package) can comprise any number of gate drivers. In one example, FIG. 1a shows the first die may comprise a single gate driver IC. However, in another example (not shown), the first die can comprise 2, 3, 4, or even more gate drivers.

The second die 2 (and therefore the semiconductor package) can comprise any number of ICs. In one example, FIG. 1a shows the second die may comprise a single IC. However, in another example (not shown), the first die can comprise 2, 3, 4, or even ICs.

The first and second dies may be made of any suitable semiconductor material. Some non-limiting examples of such materials may include silicon, polysilicon, gallium arsenide, silicon carbide, gallium nitride, silicon and germanium, and the like. Similarly, the first and second dies may comprise any suitable IC or semiconductor device. Some non-limiting examples of these devices may include diodes and/or transistors, including bipolar junction transistors (“BJT”), metal-oxide-semiconductor field-effect transistors (“MOSFET”), insulated-gate-bipolar transistors (“IGBT”), and insulated-gate field-effect transistors (“IGFET”). However, in some embodiments, the first die contains a gate driver and the second die may comprise a transistor, such as a MOSFET or IGBT.

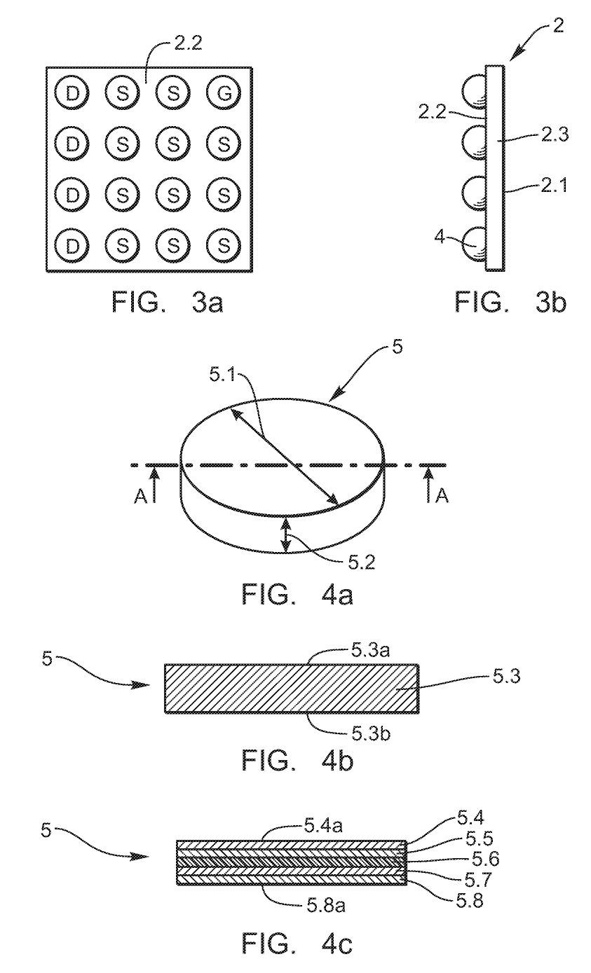

FIG. 1a shows the IC die 2 can include a first surface 2.1 and a second surface 2.2. In some cases, as shown in FIG. 1a, the second surface 1.2 of the gate driver die 1 is stacked on the first surface 2.1 of the IC die 2. FIGS. 3a and 3b show that the second surface 2.2 of the IC die 2 can comprise an active surface available for electrical connection. In particular, FIG. 3a shows the active layer 2.2 can also have terminals for at least one drain D, source S, and/or gate G.

FIG. 3b shows the IC die 2 can comprise an optional isolation layer 2.3 that can isolate the first surface 2.1 of the IC die 2. The isolation layer can be made of any suitable isolating material, including a material comprising silicon oxide. Similarly, the isolation material may be located in any suitable position, including within the die itself.

The first surface 2.1 of the IC die 2 can include a defined metal plated area that can provide for improved connection (e.g., via adhesive, soldering, etc.) to a surface, such as the second surface 1.2 of the gate driver die 1. Some non-limiting examples of suitable plating that can be used in this plated area may include NiPdAu, TiNiAgAu, TiNiAgSn, an oxidation-resistant layer, or an adhesion sublayer.

The active die surface of the IC die can be electrically and/or mechanically attached to one or more attach pads through any appropriate method or technique known in the art. Examples of these techniques include solder bumping, which may include the use of solder bumps, balls, studs, and combinations thereof. In some embodiments, FIG. 1a shows that the second surface 2.2 of the IC die 2 can be electrically and/or mechanically connected to a plurality of attach pads 5 through solder bumping comprising solder bumps 4. Similarly, FIG. 2c shows some embodiments where the second surface 2.2a of the IC die 2 is connected to an attach pad through solder bumping that includes the use of a stud bump 12, which is coupled with solder paste 4 to form a solder joint.

As previously mentioned, the semiconductor package can comprise one or more attach pads that electrically connect the IC die and/or the gate driver die with an external device, such as a PCB. The attach pads may have any characteristic that allows the IC die and/or the gate driver die to be connected to the attach pads (e.g., via bump or wire bonding) and that allows the attach pads to be electrically and/or mechanically connected to an external surface. For example, FIG. 4a shows the attach pad 5 can be substantially circular and have any suitable diameter 5.1 that allows for reliable connection (e.g., via bonding or bumping). The diameter of the attached pads may be varied according to bump diameters and die passivation diameter openings.

The attach pads may be made of any suitable material, including, but not limited to Cu, Au, Ni, Pd, and combinations thereof. In some embodiments, FIG. 4b shows the attach pad 5 may comprise Cu. In such embodiments, the surfaces 5.3a and/or 5.3b of the attach pad 5 may be left bare or may have defined surface plating, as discussed above, to improve joint reliability. In other embodiments, however, FIG. 4c shows the attach pad 5 can be a plated pad that includes multiple conductive materials. Specifically, FIG. 4c shows these embodiments where the attach pad 5 comprises a first layer of Au 5.4, a first layer of Pd 5.5, a layer of Ni 5.6, a second layer of Au 5.7, and a second layer of Pd 5.8. In these embodiments, a first surface 5.4a of the plated attach pad 5 can serve as the contacting surface (e.g., for solder bumps and/or wire bonding) and a second surface 5.8a of the attach pad can serve as the contact surface between an external surface, and/or an external solder ball 8, as shown in FIG. 2c.

The attach pad 5 can be any suitable thickness 5.2. In some embodiments, the Cu attach pad 5 shown in FIG. 4b may have a thickness from about 0.01 millimeters to about 1 millimeter. In other embodiments, however, the Cu attach pad has a thickness from about 0.05 millimeters to about 0.25 millimeters. And for the embodiments where attach pad 5 is plated (as shown in FIG. 4c), it may have an overall thickness from about 0.01 millimeters to about 0.1 millimeters thick. In other embodiments, however, the plated attach pad 5 in FIG. 4c may have a thickness of about 0.04 millimeters.

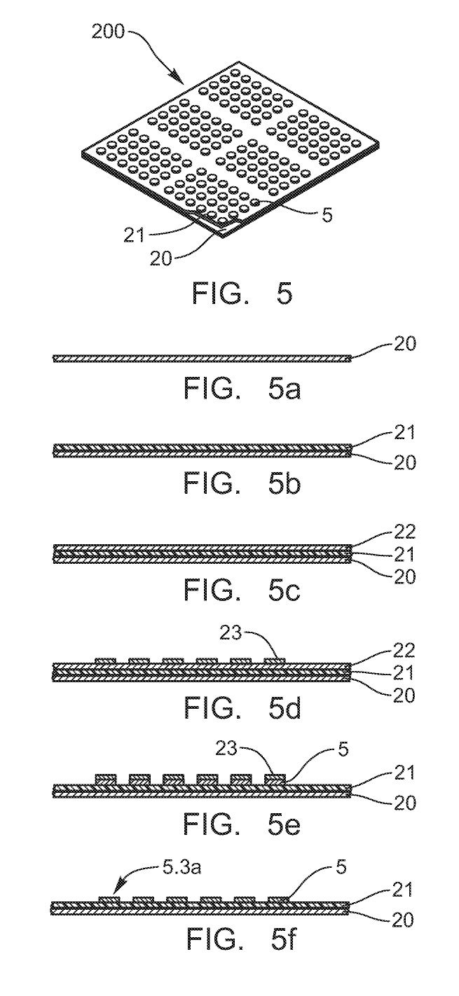

The attach pads can be formed and patterned through any process known in the art. In some embodiments, the attach pads can be formed and patterned through the use of a leadframe. In such embodiments, the leadframe may have any characteristic known in the art. For example, FIG. 5 illustrates some embodiments of a leadframe 200 that comprises a composite leadframe substrate. In this example, the leadframe 200 features an array of attach pads 5 disposed on an insulating and/or adhesive material 21, which is supported by a thin frame 20 made of a supporting material, such as Cu.

The leadframe and attach pads may be made in any known manner. By way of non-limiting example, FIG. 5a through 5f shows a possible process flow for making a leadframe substrate in which the array of attach pads is produced through the etching a leadframe that includes two Cu surfaces.

In some embodiments, FIG. 5a shows a process for producing the leadframe and attach pad array that comprises providing a first frame 20 that acts as a support. This support frame may comprise any material that supports the additional components of the leadframe, such as Cu. The first frame can be provided in any shape known in the art, including a strip or reel. And the first frame may have any suitable thickness. For instance, the first frame may have a thickness from about 0.05 millimeters to about 0.2 millimeters, or thicker or thinner, depending on the requirements of the process to maintain the planarity and prevent warping of the first frame.

FIG. 5b shows that, in some embodiments, a dual-sided adhesive material 21 may be placed on top of the support frame 20. In such embodiments, the adhesive material may have any suitable characteristic, such as thickness, insulative character, adhesiveness, etc.

Following the placement of the adhesive material 21, FIG. 5c shows that a second frame 22 can be placed on top of the adhesive material 21. The second frame may have any characteristic suitable for the fabrication of attach pads. For example, the second frame may be made of any material suitable for the production of attach pads, including, but not limited to, Cu, Au, Pd, Ni, and combinations thereof. In some embodiments, the second frame 22 comprises Cu.

The second frame may have any thickness depending on the structure needed and the material used in the second frame. For instance, a second frame comprising Cu can have a thickness from about 0.05 millimeters to about 0.25 millimeters and a second frame comprising plated Au, Pd, and/or Ni may have a thickness of about 0.04 millimeters.

Following placement of the second frame on the adhesive layer, the first frame 20 and/or the second frame 22 may be attached to the adhesive layer 21 in any conventional manner. For example, the first frame 20, the adhesive layer 21, and the second frame 22 may be put through a series of heated rollers that can press them together at a specified temperature profile to cure the adhesive material 21.

Next, at FIG. 5d, a patterned insulation layer 23 may be placed on the exposed surface of the second frame 22. The insulation material of layer 23 may have any characteristic that helps protect a portion of the second frame from an etching solution. For example, the patterned insulation layer may comprise circular forms that are placed on the second frame in a desired array arrangement. In this example, the array arrangement may be varied depending on several factors, such as the die bump pitch, the type and size of dies to be used, etc.

After the patterned insulation layer has been placed on the second frame, the exposed portion of the second frame may be removed through any known method. For example, the exposed portion of the second frame may be chemically etched away while all surfaces covered by the patterned insulation material 23 can remain on the adhesive material 21. In this manner, FIG. 5e shows an array of circular attach pads 5 may be made.

FIG. 5f shows the patterned insulation layer may be removed so that a first surface (e.g., surface 5.3a) of the attach pads 5 is exposed. While the insulation layer may be removed in any suitable manner, in some embodiments, it may be removed chemically. Additionally, as the insulation layer is removed a remaining portion of the leadframe may be cleaned.

Once the insulation layer has been removed (as shown in FIGS. 5 and 5f), the exposed upper surface of the attach pad can optionally be coated with a defined metal plating for improved joint reliability (i.e., joints formed with solder, adhesive, bonding, etc). Some non-limiting examples of suitable plating materials may include those previously mentioned, as well as Au, Ni, Ag, and/or any other plating material suitable for achieving reliable joints.

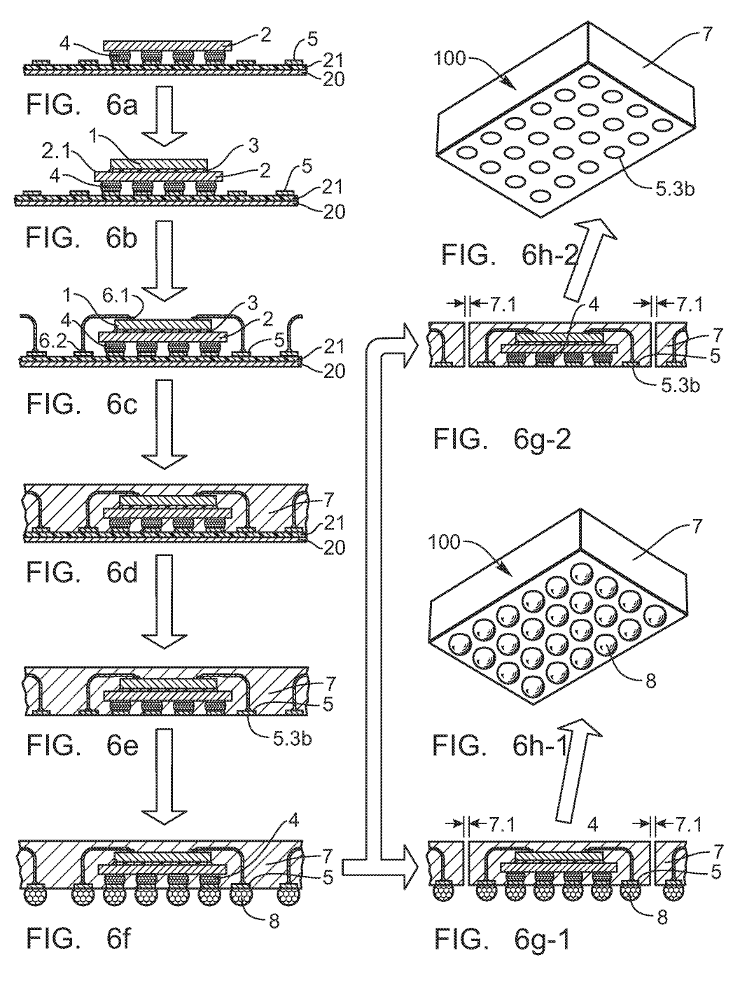

After the attach pad array and leadframe have been completed, the package may be assembled in any known manner. By way of non-limiting example, FIGS. 6a through 6h-2 illustrate an assembly flow process for assembly. FIG. 6a shows that the IC die 2 may be attached to the attach pads 5. This process can be done through any manner, including a conventional flip chip process, where the active surface of the IC die is bumped and the bumps cure and form a joint with the attach pads 5.

Next, at FIG. 6b, the gate driver die 1 may be attached to the first surface 2.1 of the IC die 2. Although the gate driver die may be attached to the IC die through any known method, in some embodiments, the gate driver may be attached with an electrically conductive or non-conductive epoxy, adhesive, solder, film, and/or clip. However, in the embodiments where it is beneficial to electrically isolate the gate driver die 1 from the IC die 2, it may be beneficial to use a method for attachment that is not electrically conductive (e.g., a non-conductive epoxy).

The gate driver die 1 that has been attached to the IC die 2 can then be electrically connected to one or more attach pads in any known manner. For example, FIG. 6c shows the gate driver 1 can be electrically connected to the attach pads 5 by wire bonding. In such instances, the bonding wire may be made of any wire bonding material and have any suitable size. Some non-limiting examples of wire bonding materials may include Au, Al, Cu, and combinations thereof other. And where Au is used, the bonding wire may have a diameter from about 0.025 millimeters to about 0.05 millimeters.

The gate driver can be electrically attached to the attach pads through wire bonding in any known manner, such as bond stitch on ball bonding (“BSOB”), standard wire looping wire bonding, trapezoidal type looping, etc. FIG. 6c shows some examples where Au bonding is applied as ball formed bonding 6.2 on the attach pad 5 and then a BSOB is formed 6.1 on a bonding surface of the gate driver 1. However, in other examples, the bonding method can alternatively apply ball form bonding as 6.1 and weld bonding as 6.2.

The stacked assembly of the first and second dies may be encapsulated in any suitable a molding material, such as the epoxy mold compound 7 in FIG. 6d, a thermoset resin, or a thermoplastic. And the encapsulation may be done by any suitable method, including transfer molding and injection.

Next, as shown in FIG. 6e, the support frame 20 and the thin adhesive material 21 may be removed from the encapsulated package. This removal process may be completed through any known method, including, but not limited to, chemical etching. During this removal process, the bottom surface of the package, and in particular, the bottom surface 5.3b of the attach pads 5 can be cleaned by the chemical etchant or through any other known method. The bottom surface 5.3b of the attach pad can optionally be plated to improve joint reliability.

FIG. 6f shows some embodiments where solder balls 8 are attached to the attach pads 5 to provide a molded BGA option. However, FIG. 6h-2 shows other embodiments of a molded LGA option where solder balls are not attached to the attach pads 5.

FIGS. 6g-1 and 6g-2 show that in either the molded BGA or the LGA embodiments, the process can include a singulation process to separate individual packages. Although the singulation process may be done in any manner known in the art, FIGS. 6g-1 and 6g-2 show some instances where the singulation process for the molded BGA and LGA options is accomplished through sawing and removing an area 7.1 between the individual packages.

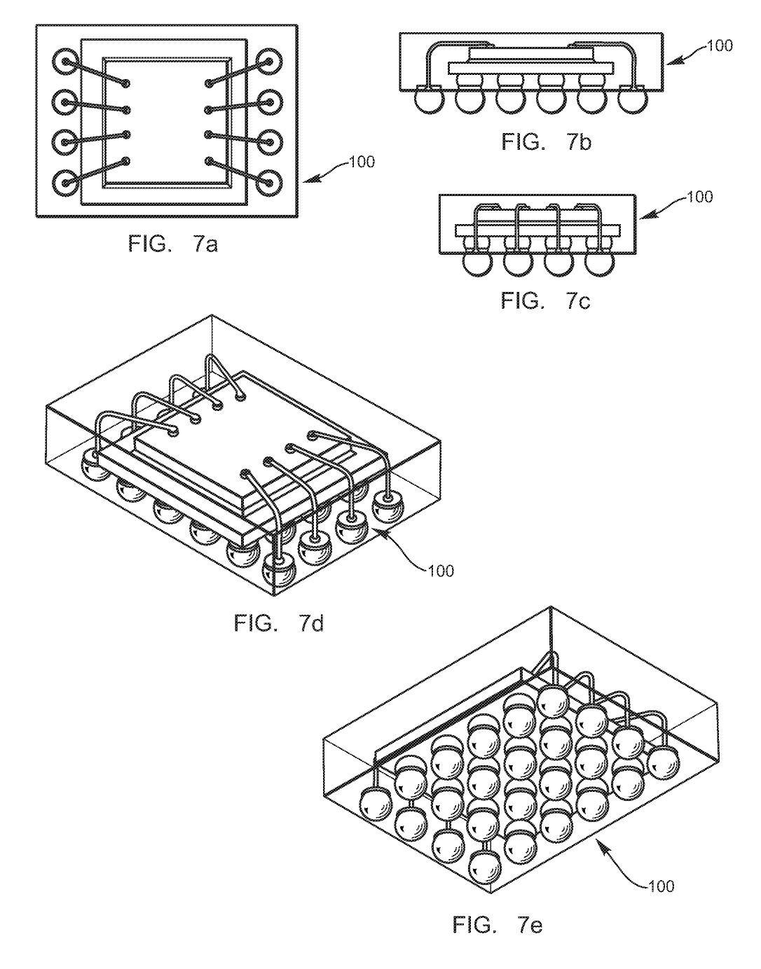

Finally, FIGS. 6h-1 and 6h-2 show the singulated packages 100 may be tested, marked, taped, and/or reeled as is known in the art. By way of illustration, FIGS. 6h-1 and 6h-2 depict some embodiments of a final molded BGA option package and a final molded LGA option package, respectively. Similarly, FIGS. 7a through 7e illustrate various 2-dimensional and 3-dimensional views of some embodiments of a final molded BGA option package.

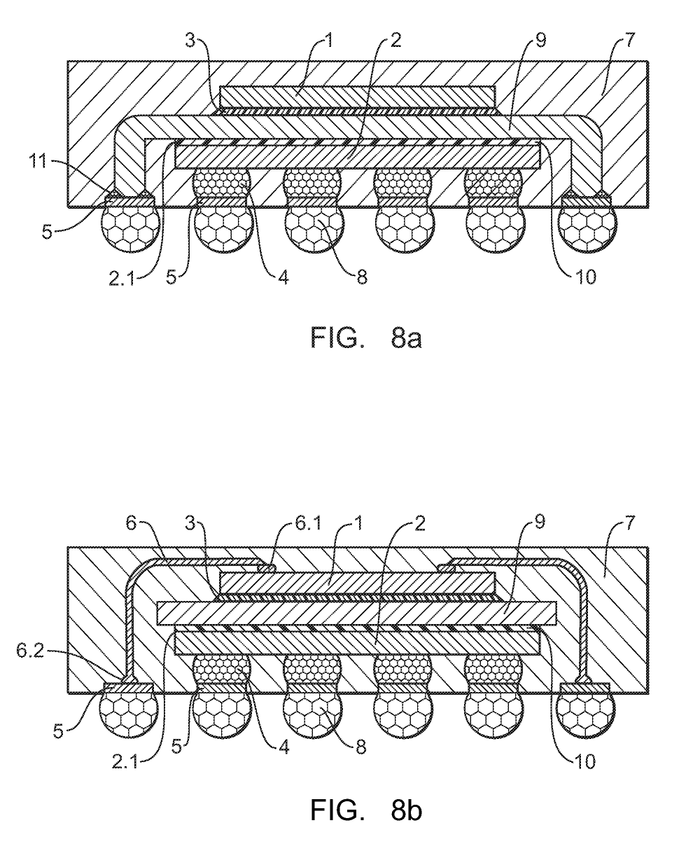

In addition to the aforementioned characteristics and components, the semiconductor package can comprise any other semiconductor component, including a leadframe clip, a diode, a transistor, etc. FIGS. 8a and 8b show some embodiments where the package comprises a leadframe clip 9. In such embodiments, the package may incorporate any known leadframe clip, including, but not limited to, a drain folded leadframe clip.

A drain folded leadframe clip can function in any manner consistent with its use in the semiconductor package. For instance, FIGS. 8a and 8b show the clip 9 can provide a surface to which the gate driver die 1 can be attached (e.g., via a die attach epoxy 3, an adhesive, a film, etc.). Moreover, FIGS. 8a and 8b show the clip 9 can be electrically and/or mechanically connected in any known manner (e.g., a die attach epoxy 10, and conductive adhesive/paste, a non-conductive adhesive/paste, etc.) to the first surface 2.1 of the IC die 2. However, because the leadframe clip 9 connects to the drain on the first surface of the IC die, in some cases it may be beneficial to electrically connect the IC die and the leadframe clip.

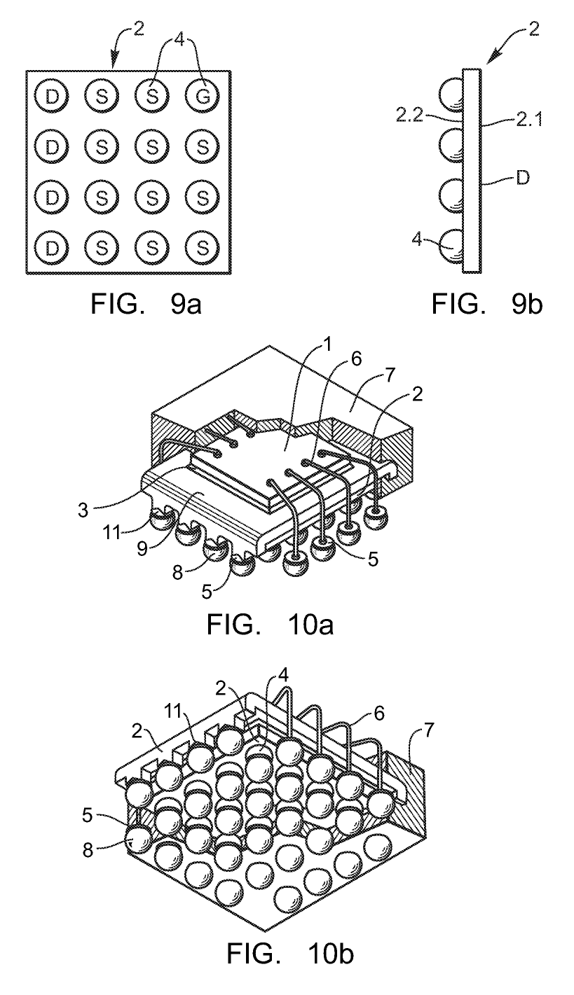

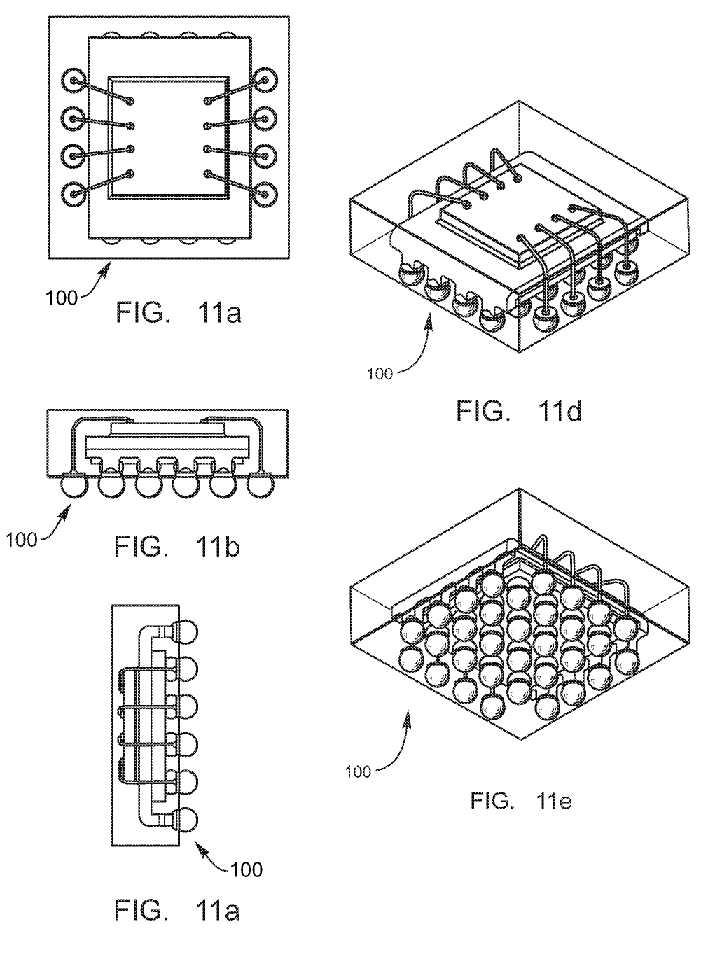

When the leadframe clip 9 connects to the drain on the first surface 2.1 of the IC die 2, the IC die may be configured to be used with the clip. In some embodiments, FIG. 9b shows that a drain D can be located on the first surface 2.1 of the IC die. In these embodiments, the first surface 2.1 may optionally be plated with a suitable metal plating (as discussed above) so as to increase the joint reliability between the first surface 2.1 and the clip 9. FIGS. 9a and 9b show other embodiments where the IC die 2 has solder bumps 4 attached to the active surface 2.2 of the IC die. Particularly, FIG. 9a shows that the active surface can comprises one gate G and a plurality of sources S.

The leadframe clip 9 can be electrically and/or mechanically connected to one or more attach pads in any known manner. For example, FIG. 8a shows that the leadframe clip 9 can be connected to a plurality of attach pads 5 through the use of a solder paste epoxy 11.

A semiconductor package that comprised the leadframe clip 9 can have either an LGA or a BGA configuration. By way of non-limiting example, FIG. 10a, 10b, and 11a through 11e show several views of a BGA package that comprises a leadframe clip 9.

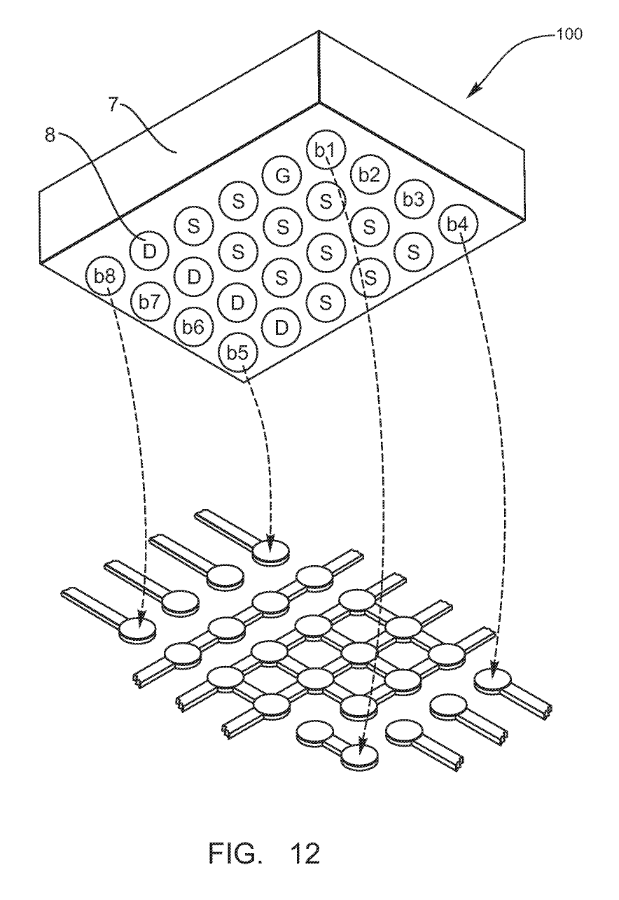

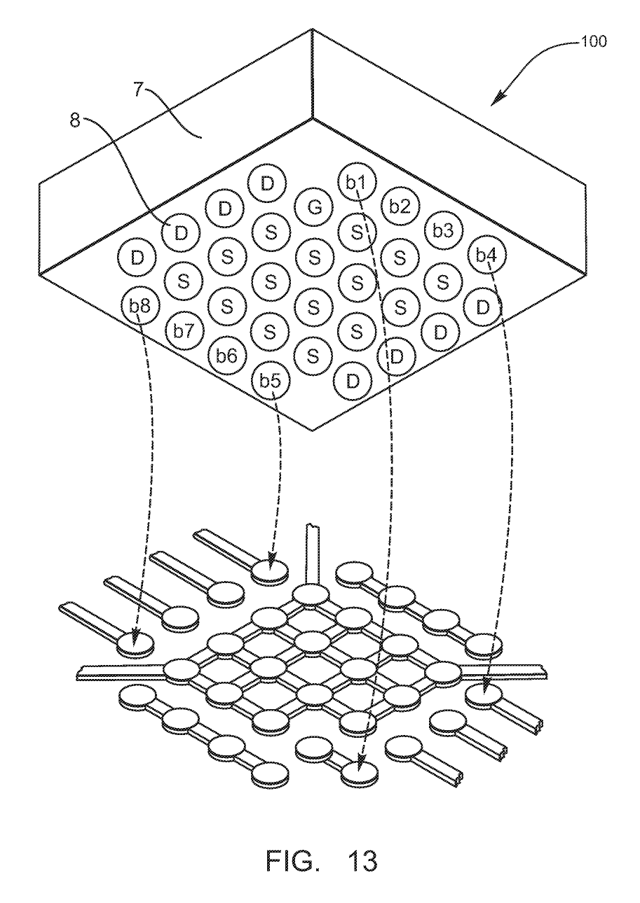

The semiconductor package may be configured to be used with any land pattern. FIGS. 12 and 13 show some examples of one land pattern that can be used. Specifically, FIG. 12 shows a land pattern of the BGA option of the package that does not comprise the leadframe clip and FIG. 13 shows a land pattern of the BGA option of the package that comprise a leadframe clip.

In FIGS. 12 and 13, each solder ball 8 is labeled according to its function. Specifically, G, S, and D refer to the gate, source, and drain from the IC in die 2 and/or from the IC via the leadframe clip 9 (as shown in FIG. 13) and b1-b8 refer to the solder ball terminals for the gate driver. In FIGS. 12 and 13, b1 depicts the output of the gate driver and b2 through b8 depict the terminals where the gate driver can take its voltage supply, grounding, input signal, feedback signal, and/or other input. In both FIGS. 12 and 13, the output b1 of the gate driver is oriented near to the gate G so that during mounting to an external surface (e.g., a PCB) the output b1 can be directly connected with the gate G.

The semiconductor packages described herein may be used in any electronic apparatus or device known in the art. In some non-limiting examples, the semiconductor package can be used in any type of electronic device, including those mentioned above, as well as in logic or analog devices.

The semiconductor packages described herein may offer several advantages. First, as previously mentioned, the semiconductor package can comprise a stacked die assembly with both an IC die and a gate driver die. Accordingly, the package may be more conveniently used and save more space on a circuit board layout than other packages that do not stack the gate driver die on top of the IC die. Second, because the semiconductor package may be thin (e.g., have a total thickness from about 0.60 millimeters to about 1.20 millimeters), comprise a small package size, and/or a small footprint; it can be used in condensed assemblies, including those for ultra portable application. Third, because the IC die can comprise solder bumps and/or studs that are directly connected to the attach pads, which serve as terminals for an external source, the package may provide a better Rds response that is lower than semiconductors packages that simply use wire bonded die.

Having described the preferred aspects of the semiconductor package and associated methods, it is understood that the appended claims are not to be limited by particular details set forth in the description presented above, as many apparent variations thereof are possible without departing from the spirit or scope thereof.

1. A semiconductor package, comprising:
a first integrated circuit die that is electrically connected to multiple attach pads through wire bonding; and
a second integrated circuit die that is electrically connected to multiple attach pads through solder bumping;
wherein the first die is stacked on the second die and the first die and the second die are encapsulated in an encapsulation material.

2. The semiconductor package of claim 1, wherein the first integrated circuit comprises a gate driver.

3. The semiconductor package of claim 1, wherein the second integrated circuit comprises a transistor.

4. The semiconductor package of claim 3, wherein the transistor comprises a MOSFET or an IGBT integrated circuit.

5. The semiconductor package of claim 1, wherein the attach pads comprise copper.

6. The semiconductor package of claim 5, wherein the attach pads are plated with Au, Ni, Pd, or combinations thereof.

7. The semiconductor package of claim 1, wherein the package comprises a ball grid array molded package that includes solder balls attached to the attach pads.

8. The semiconductor package of claim 1, wherein the package comprises a land grid array molded package without solder balls attached to the attach pads.

9. The semiconductor package of claim 1, further comprising a drain folded leadframe clip connected to the drain of integrated circuit in the second die.

10. The semiconductor package of claim 9, wherein the first die is stacked on the leadframe clip and the leadframe clip is stacked on the second die.

11. An electronic apparatus containing a semiconductor package, the package comprising:
a first integrated circuit die that is electrically connected to multiple attach pads through wire bonding; and
a second integrated circuit die that is electrically connected to multiple attach pads through solder bumping;
wherein the first die is stacked on the second die and the first die and the second die are encapsulated in an encapsulation material.

12. The electronic apparatus of claim 11, wherein the first die comprises a gate driver.

13. The electronic apparatus of claim 11, wherein the second die comprises a MOSFET integrated circuit.

14. The electronic apparatus of claim 11, wherein the semiconductor package further comprises a drain folded leadframe clip that is connected to the drain of the integrated circuit of the second die.

15. The electronic apparatus of claim 14, wherein the first die is stacked on the leadframe clip and the leadframe clip is stacked on the second die.

16. The electronic apparatus of claim 11, wherein the electronic apparatus comprising an electrical device containing a surface to which the attach pads are connected.

17. A method for making a semiconductor package with a stacked die assembly, the method comprising:
providing a stacked die assembly comprising a first integrated circuit die stacked on a second integrated circuit die;
attaching the second die to multiple attach pads through solder bumping;
attaching the first die to multiple attach pads by wire bonding; and
encapsulating the first die, the second die, and the attach pads so that a portion of the attach pads is externally exposed from the package.

18. The method of claim 17, further comprising stacking a leadframe clip between the first die and the second die.

19. The method of claim 17, wherein the second die comprises a MOSFET integrated circuit.

20. The method of claim 17, wherein the first die comprises a gate driver integrated circuit.

21. The method of claim 17, wherein the attach pads are made by a method comprising:
providing a first frame;
placing an adhesive material on the first frame;
placing a second frame on the adhesive material;
placing a patterned insulation material on the second frame;
removing a portion of the second frame that is not covered by the insulation material; and
removing the insulation material to expose a surface of the attach pads that is adapted to be joined to the first die.

22. A semiconductor package, comprising:
a first die comprising a gate driver that is electrically connected to multiple attach pads through wire bonding; and
a second die comprising a transistor that is electrically connected to multiple attach pads through solder bumping;
wherein the gate driver is stacked on the transistor and the gate driver, the transistor, and the attach pads are encapsulated so that a portion of the attach pads is externally exposed from the package.

23. The semiconductor package of claim 22, wherein the transistor is comprises a MOSFET integrated circuit.

24. The semiconductor package of claim 22, wherein the package comprises a molded ball grid array package with solder balls attached to the externally exposed portion of the attach pads.

25. The semiconductor package of claim 22, wherein the package further comprises a leadframe clip stacked between the transistor and the gate driver.
